(19) United States
(12) Patent Application Publication
(10) Pub. No.: US 2026/0193051 A1
(43) Pub. Date: Jul. 9, 2026

(54) METAL WIRE BOBBIN DEVICE FOR GRAPHENE DEPOSITION

(71) Applicant: CHARMGRAPHENE Co., Ltd., Suwon-si (KR)

(72) Inventor: Yong Ki KIM, Suwon-si (KR)

(73) Assignee: CHARMGRAPHENE Co., Ltd., Suwon-si (KR)

(21) Appl. No.: 19/047,176

(22) Filed: Feb. 6, 2025

(30) Foreign Application Priority Data
Jan. 3, 2025 (KR) 10-2025-0000807

(51) Int. Cl. B65H 75/08; B65H 54/00

(52) U.S. Cl. CPC B65H 75/08; B65H 54/00; B65H 2701/36

(57) ABSTRACT

The present invention relates to a metal wire bobbin device for graphene deposition, and more specifically, to a metal wire bobbin device for graphene deposition that enables the deposition of graphene on metal wires by unwinding and rewinding the wire in an organized manner before feeding it into a deposition apparatus. The present invention provides a metal wire bobbin device for graphene deposition, comprising: a vertical body unit including a vertically-oriented frame with open front and rear sides, and a vertical wire seating portion installed on the vertical frame; and a horizontal body unit rotatably installed inside the vertical body unit, including a horizontally-oriented frame and a horizontal wire seating portion installed on the horizontal frame.

### TECHNICAL FIELD

The present invention relates to a bobbin device for a metal wire used in graphene deposition. More specifically, it pertains to a bobbin device for graphene deposition on metal wire, which enables the deposition of graphene on the metal wire by evenly unwinding and rewinding the metal wire before feeding it into a deposition apparatus.

### BACKGROUND ART

Graphene is a thin-film material in which carbon atoms are arranged in a two-dimensional structure. Due to its internal characteristics, where charges act as zero effective mass particles, graphene exhibits extremely high electrical conductivity. It is also known to have high thermal conductivity, elasticity, and other favorable properties. Additionally, studies have reported that graphene is advantageous for high-frequency signal transmission with minimal noise interference, even at narrow linewidths.

Graphene can be manufactured not only in flat sheet form but also in wire form. Due to its excellent shielding performance against high-frequency signals and other interferences, it can be applied to wiring in circuit boards essential for electrical and electronic devices, as well as in transparent displays, flexible displays, and audio equipment.

Korean Patent Publication No. 10-2024-0106062 (Graphene Deposition Device for Metal Wire, published on July 8, 2024) describes a technology related to a graphene deposition device for metal wire. This technology discloses a deposition device for manufacturing metal wire with graphene in a roll-to-roll process.

However, the aforementioned technology has limitations in the amount of wire that graphene can be deposited on due to the roll-to-roll deposition process. Additionally, as the number of wire strands for deposition increases, the number of rollers required also increases, leading to the problem of needing a larger number of rollers to be installed. Furthermore, the increase in the number of rollers inherently results in the deposition device becoming larger in size.

### DISCLOSURE

### Technical Problem

The present invention has been devised to solve the aforementioned issues and aims to provide a metal wire bobbin device for graphene deposition, capable of producing large quantities of wires for graphene deposition.

The present invention also aims to provide a metal wire bobbin device for graphene deposition that maximizes the amount of wire that can be deposited in a single process using the deposition apparatus.

### Technical Solution

To achieve the above objects, the present invention provides a metal wire bobbin device for graphene deposition, comprising: a vertical body unit including a vertical frame with open front and rear sides, and a vertical wire seating portion installed on the vertical frame; and a horizontal body unit rotatably installed inside the vertical body unit, including a horizontal frame and a horizontal wire seating portion installed on the horizontal frame.

In the present invention, the vertical body unit comprises: a pair of support shafts installed on both sides of the center of the vertical frame; a rotational drive portion consisting of a pair of drive shafts installed on the inner sides of the support shafts to rotationally drive the horizontal body unit, and a handle provided on one of the drive shafts; a vertical frame consisting of a pair of side frames where the support shafts are installed, an upper frame connecting the tops of the side frames, and a lower frame connecting the bottoms of the side frames; and a vertical wire seating portion consisting of an upper wire seating portion mounted on the upper part of the side frames and a lower wire seating portion mounted on the lower part of the side frames.

In the invention, the upper wire seating portion comprises: an upper winding part including an upper winding bar on which the metal wire is wound on its upper surface, and a pair of upper joint hole parts formed at both ends of the upper winding bar; and a pair of upper joint parts fastened to the upper joint hole parts from the outside of the side frame to secure both sides of the upper winding part to the side frame, and the lower wire seating portion comprises: a lower winding part including a lower winding bar on which the metal wire is wound on its lower surface, and a pair of lower joint hole parts formed at both ends of the lower winding bar; and a pair of lower joint parts fastened to the lower joint hole parts from the outside of the side frame to secure both sides of the lower winding part to the side frame.

In the present invention, the upper joint part comprises: an upper joint plate with multiple bolt holes, an upper spring first support end mounted on the upper joint plate, an upper spring second support end mounted on the top of the side frame, an upper spring connecting the upper spring first and second support ends, and multiple upper bolts fastening the upper joint plate to the side frame and the upper joint hole part, and the lower joint part comprises: a lower joint plate with multiple bolt holes, a lower spring first support end mounted on the lower joint plate, a lower spring second support end mounted on the bottom of the side frame, a lower spring connecting the lower spring first and second support ends, and multiple lower bolts fastening the lower joint plate to the side frame and the lower joint hole part.

In the present invention, the side frame is provided with an upper guide hole and a lower guide hole of a predetermined length, allowing upward and downward movement due to the elastic force of the upper spring and lower spring, respectively, when some of the upper bolts and lower bolts fastened to the side frame through the upper joint plate and lower joint plate are removed.

In the present invention, the upper wire seating portion is further equipped with multiple upper layered winding parts above the upper winding part, with the width of the upper layered winding parts increasing progressively from lower layer to upper layer, and the lower wire seating portion is further equipped with multiple lower layered winding parts below the lower winding part, with the width of the lower layered winding parts increasing progressively from upper layer to lower layer.

In the present invention, the upper layered winding parts comprise multiple upper layered winding bars sequentially stacked above the upper winding bar and upper fixing fasteners formed on both sides of the upper layered winding bars, and the lower layered winding parts comprise multiple lower layered winding bars sequentially stacked below the lower winding bar and lower fixing fasteners formed on both sides of the lower layered winding bars.

In the present invention, the horizontal body unit comprises: a pair of rotating shafts mounted on the inner sides of the side frame, connected to the drive shaft for rotation, with one of the rotating shafts connected to the drive shaft equipped with the handle, enabling simultaneous rotation by the handle's operation; a horizontal frame comprising a pair of side bodies where the rotating shafts are mounted, a front body connecting the front ends of the side bodies, and a rear body connecting the rear ends of the side bodies; and a horizontal wire seating portion comprising a front wire seating portion mounted at the front end of the side bodies and a rear wire seating portion mounted at the rear end of the side bodies.

In the present invention, the front wire seating portion comprises a front winding bar on which the metal wire is wound on its front surface, and a pair of front joint bolts for securing both sides of the front winding bar to the side body, and the rear wire seating portion comprises a rear winding bar on which the metal wire is wound on its rear surface, and a pair of rear joint bolts for securing both sides of the rear winding bar to the side body.

In the present invention, the front wire seating portion is further equipped with multiple front layered winding bars mounted in front of the front winding bar, and the rear wire seating portion is further equipped with multiple rear layered winding bars mounted behind the rear winding bar.

In the present invention, the front wire seating portion can be rotated or fixed using the front joint bolts, and the rear wire seating portion can be rotated or fixed using the rear joint bolts.

### Advantageous Effects

The metal wire bobbin device for graphene deposition according to the present invention has the advantage of enabling the mass production of graphene-deposited wire at a low cost, as it allows a large amount of wire to be processed at once using the deposition apparatus.

Furthermore, the metal wire bobbin device for graphene deposition according to the present invention has the advantage of maximizing the amount of wire that can be subjected to graphene deposition in a single process, as it allows a large amount of wire to be wound at once and fed into the deposition apparatus.

### DESCRIPTION OF DRAWINGS

FIG. 1 is a perspective view of the metal wire bobbin device for graphene deposition according to an embodiment of the present invention.

FIG. 2 is an exploded perspective view of the metal wire bobbin device for graphene deposition according to an embodiment of the present invention.

FIG. 3 is a perspective view of the vertical body unit of the bobbin device shown in FIG. 2.

FIG. 4 is an exploded perspective view of the vertical wire seating portion of the vertical body unit shown in FIG. 3.

FIG. 5 is a perspective view of the horizontal body unit of the bobbin device shown in FIG. 2.

FIG. 6 is an exploded perspective view of the horizontal body unit shown in FIG. 5.

FIG. 7 is a usage state view showing the process of winding metal wire using the metal wire bobbin device for graphene deposition according to an embodiment of the present invention.

FIG. 8 is a usage state view showing the completed state after repeatedly winding metal wire onto the bobbin device shown in FIG. 7.

FIG. 9 is a side view illustrating the movement relationship between the vertical wire seating portion and the horizontal wire seating portion after completing the winding process shown in FIGS. 7 and 8.

FIG. 10 is a perspective view of the vertical body unit and horizontal body unit feeding it into a deposition chamber after winding metal wire onto the bobbin device according to the present invention.

### MODE FOR DISCLOSURE

Hereinafter, preferred embodiments of the present invention will be described in detail with reference to the accompanying drawings. However, this is merely for the purpose of providing a detailed explanation to enable those skilled in the art to easily carry out the invention, and it is not intended to limit the technical spirit and scope of the present invention. In describing various embodiments of the present invention, the same reference numerals will be used for components having the same technical features.

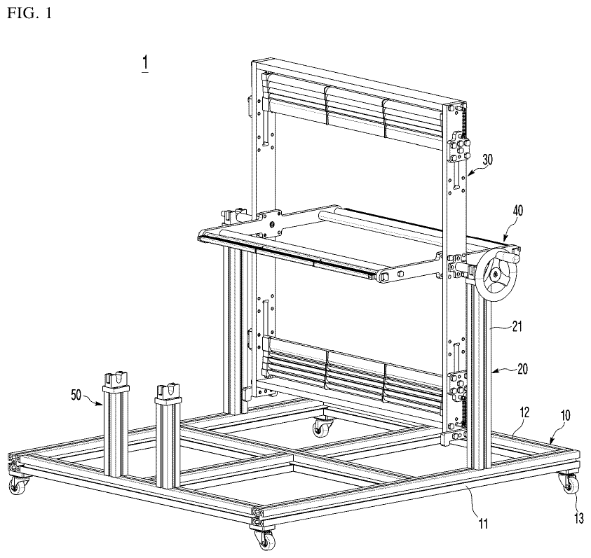

FIG. 1 is a perspective view of the metal wire bobbin device (1) for graphene deposition according to one embodiment of the present invention. As shown in the drawing, the bobbin device (1) includes a vertical body unit (30) and a horizontal body unit (40). Specifically, the configuration of the vertical body unit (30) and the horizontal body unit (40) allows metal wire (110) to be wound. For efficient winding, the vertical body unit (30) is installed to be supported by a support structure (20) mounted on the upper part of a base frame (10). The base frame (10) consists of a vertically-oriented frame (11) and a horizontally-oriented frame (12). Casters (13) for mobility can be provided on the bottom surface of the base frame (10). At the front of the base frame (10), a roller mounting unit (50) for holding the metal wire wound in rolls can be provided. The roller mounting unit (50) consists of a pair of roller supports (51) and roller mounting grooves (52) formed at the tops of the roller supports (51). Additionally, a vertical body mounting unit (20) is further provided on the base frame (10). The vertical body mounting unit (20) includes a vertical body support (21) and a support shaft groove (22) formed at the top of the vertical body support (21). The vertical body unit (30) is mounted on the vertical body mounting unit (20), and the horizontal body unit (40) is installed inside the vertical body unit (30). The vertical body unit (30) comprises a vertical frame (33) with open front and rear sides and a vertical wire seating portion (34) installed on the vertical frame (33).

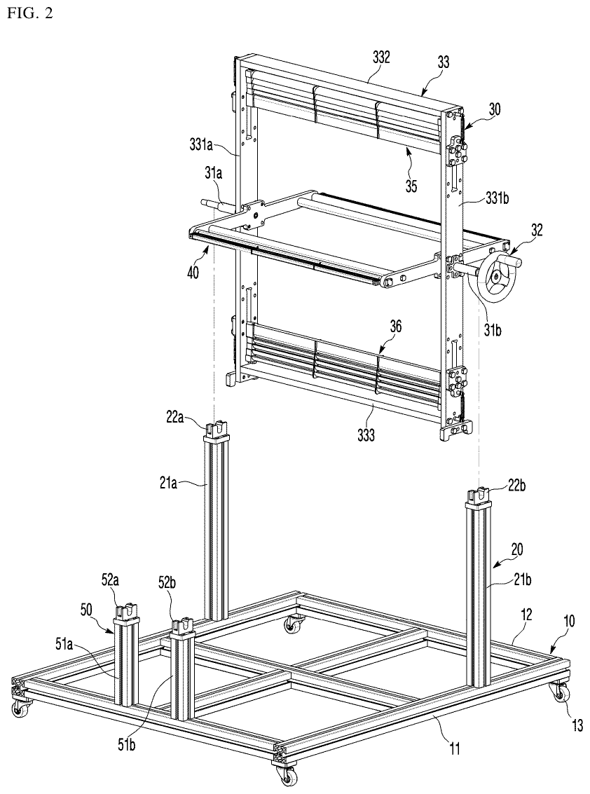

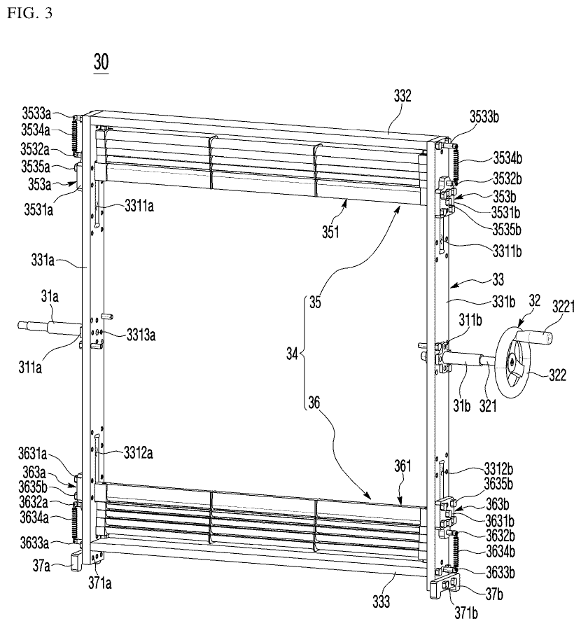

The vertical body unit (30) will be described in detail with reference to FIGS. 2 and 3. The vertical body unit (30) includes a pair of support shafts (31) installed on both sides of the center of the vertical frame (33), and a rotational drive portion (32) connected to the support shafts (31). The rotational drive portion (32) is configured to rotationally drive the horizontal body unit (40). Additionally, the rotational drive portion (32) is designed to rotationally drive the entire vertical body unit (30) and horizontal body unit (40) when the horizontal body unit (40) is fixed to the vertical body unit (30) by a stopper (46). Specifically, the rotational drive portion (32) includes a pair of drive shafts (321) installed on the inner sides of the support shafts (31) to rotationally drive the horizontal body unit (40), and a handle (322) provided on one of the drive shafts (321), equipped with a grip (3221). The vertical frame (33) consists of a pair of side frames (331: 331a, 331b) where the support shafts (31) are installed, an upper frame (332) connecting the tops of the side frames (331), and a lower frame (333) connecting the bottoms of the side frames (331). The inner sides of the pair of side frames (331) are equipped with a vertical wire seating portion (34). The vertical wire seating portion (34) comprises an upper wire seating portion (35) mounted on the upper inner side of the side frames (331), and a lower wire seating portion (36) mounted on the lower inner side of the side frames (331).

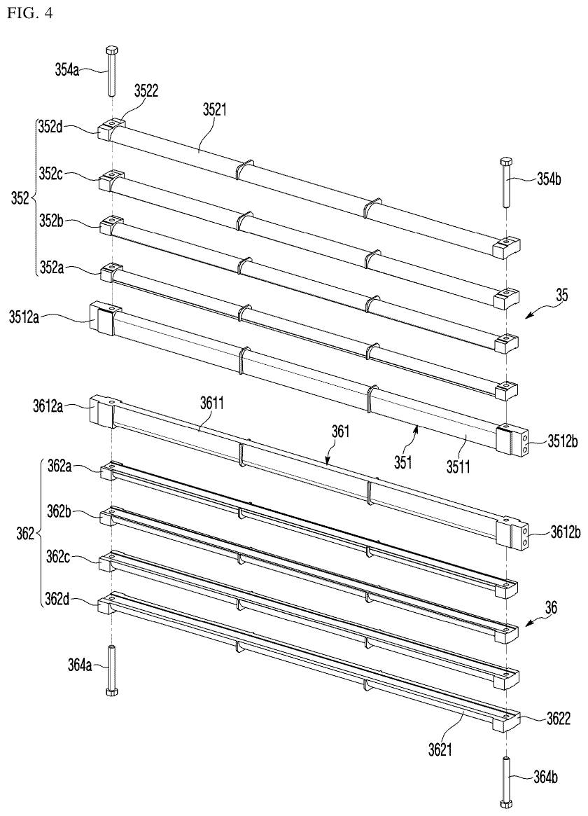

The upper wire seating portion (35) and lower wire seating portion (36), which form the vertical wire seating portion (34), will be described in detail with reference to FIGS. 3 and 4.

As shown in FIGS. 3 and 4, the upper wire seating portion (35) consists of an upper winding part (351) and a pair of upper joint parts (353). The upper winding part (351) includes an upper winding bar (3511), on which the metal wire (110) is wound on its upper surface, and a pair of upper joint hole parts (3512: 3512a, 3512b) formed at both ends of the upper winding bar (3511). The upper joint parts (353) are designed to secure both sides of the upper winding part (351) to the side frames (331). The upper joint parts (353: 353a, 353b) are paired and fastened to both sides of the upper joint hole parts (3512), thereby fixing the upper wire seating portion (35) to the side frames (331). The upper surface of the upper winding bar (3511) is arched to prevent damage to the wire (110) wound on it. The upper wire seating portion (35) is further equipped with multiple upper layered winding parts (352) above the upper winding part (351). Each upper layered winding part (352) consists of an upper layered winding bar (3521) and upper fixing fasteners (3522). The upper layered winding bars (3521), like the upper winding bar (3511), have an arched upper surface. The upper layered winding parts (352: 352a, 352b, 352c, 352d) are arranged such that their width increases progressively from lower layer to upper layer. This configuration ensures that the wire (110) wound on the winding bars is maintained at predetermined intervals, preventing interference between layers. The upper joint parts (353: 353a, 353b) consist of an upper joint plate (3531: 3531a, 3531b) with multiple bolt holes, upper spring first support ends (3532: 3532a, 3532b) mounted on the upper joint plate (3531), upper spring second support ends (3533: 3533a, 3533b) mounted on the top of the side frames (331), upper springs (3534: 3534 a, 3534b) connecting the first and second support ends, and multiple upper bolts (3535: 3535a, 3535b) for fastening the upper joint plate (3531) to the side frames (331) and the upper joint hole parts (3512). The upper joint parts (353) are configured to ensure that the wire (110) wound on the winding bar can be held taut after winding. With the upper springs (3534) provided on both sides, the upper wire seating portion (35) moves upward due to the tension of the upper springs (3534) after the wire (110) is wound on the winding bar, making the wire taut. If some of the upper bolts (3535) on the upper joint plate (3531) are loosened while the rest remain fastened to the upper joint hole parts (3512), the reduced fastening force allows the upper wire seating portion (35) to move upward due to the elastic force of the upper springs (3534). If necessary, the bolts fastened to the upper joint hole parts (3512) can also be loosened to facilitate upward movement of the upper wire seating portion (35). To accommodate this movement, the side frames (331) are provided with upper guide holes (3311: 3311a, 3311b) of a predetermined length, allowing the upper bolts (3535) fastened to the upper joint hole parts (3512) to slide as the upper wire seating portion (35) moves upward.

As shown in FIGS. 3 and 4, the lower wire seating portion (36) also consists of a lower winding part (361) and a pair of lower joint parts (363) and is symmetrically formed relative to the upper wire seating portion (35). Specifically, the lower winding part (361) includes a lower winding bar (3611), on which the metal wire (110) is wound on its lower surface, and a pair of lower joint hole parts (3612: 3612a, 3612b) formed at both ends of the lower winding bar (3611). The lower joint part (363) is designed to secure the sides of the lower winding part (361) to the side frames (331). The lower joint parts (363: 363a, 363b) are paired and fastened to the lower joint hole parts (3612), thereby fixing the lower wire seating portion (36) to the side frames (331). The lower surface of the lower winding bar (3611) is arched to prevent damage to the wire (110) wound on it, similar to the upper winding bar (3511). The lower wire seating portion (36), like the upper wire seating portion (35), is further equipped with multiple lower layered winding parts (362) below the lower winding part (361). Each lower layered winding part (362) consists of a lower layered winding bar (3621) and lower fixing fasteners (3622). The lower layered winding bars (3621), like the lower winding bar (3611), have an arched lower surface. The lower layered winding parts (362: 362a, 362b, 362c, 362d) are arranged such that their width increases progressively from top to bottom. This configuration ensures that the wires (110) wound on the winding bars are maintained at predetermined intervals, preventing interference between layers. The lower joint parts (363: 363a, 363b) consist of a lower joint plates (3631: 3631a, 3631b) with multiple bolt holes, lower spring first support ends (3632: 3632a, 3632b) mounted on the lower joint plates (3631), lower spring second support ends (3633: 3633a, 3633b) mounted at the bottom of the side frames (331), lower springs (3634: 3634a, 3634b) connecting the first and second support ends, and multiple lower bolts (3635: 3635a, 3635b) for fastening the lower joint plates (3631) to the side frames (331) and the lower joint hole parts (3612). The lower joint parts (363), together with the upper joint parts (353), is configured to allow the wire (110) wound on the winding bar to be held taut after winding. With the lower springs (3634) provided on both sides, the lower wire seating portion (36) moves downward due to the tension of the lower springs (3634) after the wire (110) is wound on the winding bar, making the wire taut. If some of the lower bolts (3635) on the lower joint plates (3631) are loosened while the rest remain fastened to the lower joint hole parts (3612), the reduced fastening force allows the lower wire seating portion (36) to move downward due to the elastic force of the lower springs (3634). If necessary, the bolts fastened to the lower joint hole parts (3612) can also be loosened to facilitate downward movement of the lower wire seating portion (36). To accommodate this movement, the side frames (331) are provided with lower guide holes (3312: 3312a, 3312b) of a predetermined length, allowing the lower bolts (3635) fastened to the lower joint hole parts (3612) to slide as the lower wire seating portion (36) moves downward.

Additionally, as shown in FIG. 3, the lower end of the side frame (331) is equipped with footrests (37: 37a, 37b) that allow the vertical body unit (30) to stand upright. These footrests are securely mounted using footrest bolts (371: 371a, 371b).

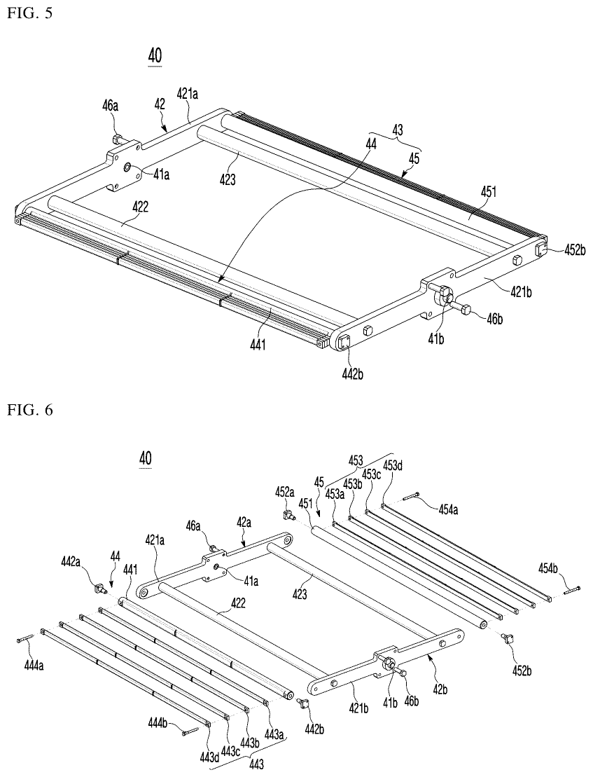

FIGS. 5 and 6 illustrate the horizontal body unit (40). As shown in the drawings, the horizontal body unit (40) is equipped with a pair of rotating shafts (41: 41a, 41b) connected to the drive shaft (321). The rotating shafts (41) are mounted on the horizontal frame (42), and the horizontal frame (42) is fitted with a horizontal wire seating portion (43). Specifically, the rotating shafts (41) are mounted on the inner sides of the side frame (331) to allow rotation, connected to the drive shaft (321). One of the rotating shafts (41) is linked to a drive shaft equipped with a handle (322) and can rotate along with the handle (322). In the drawing, the rotating shaft (41b) of the opposite side body (421b) is connected to the drive shaft (321b) where the handle (322) is mounted. The horizontal frame (42) consists of a pair of side bodies (421: 421a, 421b) where the rotating shafts (41) are mounted, a front body (422) connecting the front ends of the side bodies (421), and a rear body (423) connecting the rear ends of the side bodies (421). The horizontal wire seating portion (43) comprises a front wire seating portion (44) and a rear wire seating portion (45). The front wire seating portion (44) is mounted on the inner front end of the side bodies (421), while the rear wire seating portion (45) is mounted on the inner rear end of the side bodies (421). The front wire seating portion (44) consists of a front winding bar (441) on which the metal wire (110) is wound on its front side, and a pair of front joint bolts (442: 442a, 442b) that secure both sides of the front winding bar (441) to the side bodies (421). The front wire seating portion (44) can be rotated or fixed using the front joint bolts (442). After the metal wire (110) is wound onto the winding bar, the horizontal body unit (40) is rotated. Once the horizontal body unit (40) is rotated, the front wire seating portion (44) is also rotated to ensure that the wire (110) maintains a uniform spacing front-to-back. Additionally, the front wire seating portion (44) can be further equipped with multiple front layered winding bars (443: 443a, 443b, 443c, 443d) mounted in front of the front winding bar (441). The front layered winding bars (443) help maintain the wire (110) at predetermined intervals front-to-back, enabling the deposition of a large amount of wire in a single process.

Additionally, the rear wire seating portion (45) consists of a rear winding bar (451), on which the metal wire (110) is wound on its rear surface, and a pair of rear joint bolts (452: 452a, 452b) that secure both sides of the rear winding bar (451) to the side bodies (421). The rear wire seating portion (45) can be rotated or fixed using the rear joint bolts (452). After the metal wire (110) is wound onto the winding bar, the horizontal body unit (40) is rotated. Once the horizontal body unit (40) is rotated, the rear wire seating portion (45) is also rotated to ensure that the wire (110) maintains a uniform spacing front-to-back. Additionally, the rear wire seating portion (45) can be further equipped with multiple rear layered winding bars (453: 453a, 453b, 453c, 453d) mounted behind the rear winding bar (451). Together with the front layered winding bars (443), the rear layered winding bars (453) help maintain the wire (110) at predetermined intervals front-to-back, enabling the deposition of a large amount of wire in a single process.

Additionally, the horizontal wire seating portion (43) must wind the wire (110) while maintaining a “+” shape together with the vertical wire seating portion (34). Therefore, the horizontal body unit (40) is secured in a “+” shape relative to the vertical body part (30) by fixing both side bodies (421) to both side frames (331) using stoppers (46: 46a, 46b). As a result, the rotation of only the side bodies (421) is prevented. The stopper (46) uses bolts and may be provided on only one side. Furthermore, the stopper (46) prevents the rotation of only the horizontal body unit (40), causing it to rotate together with the vertical body unit (30).

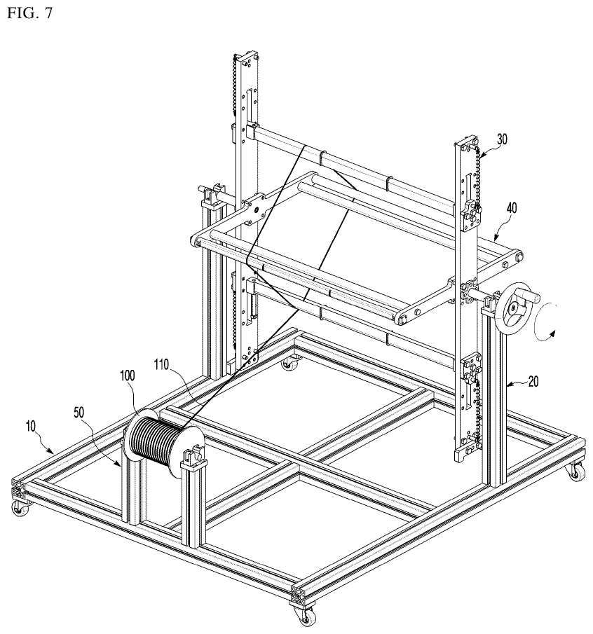

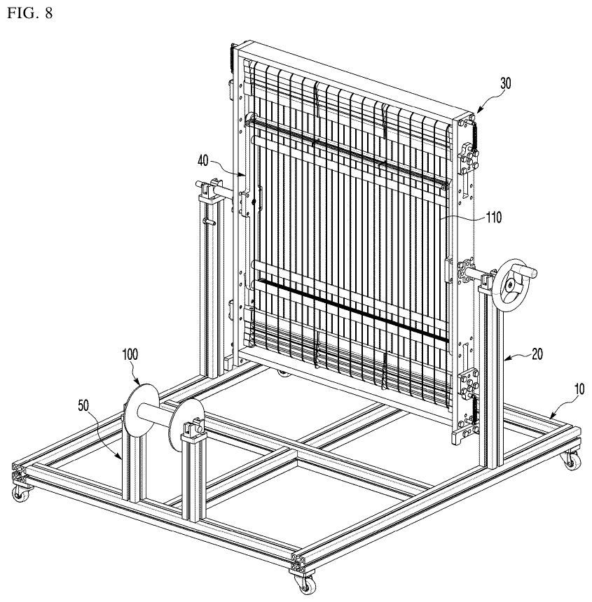

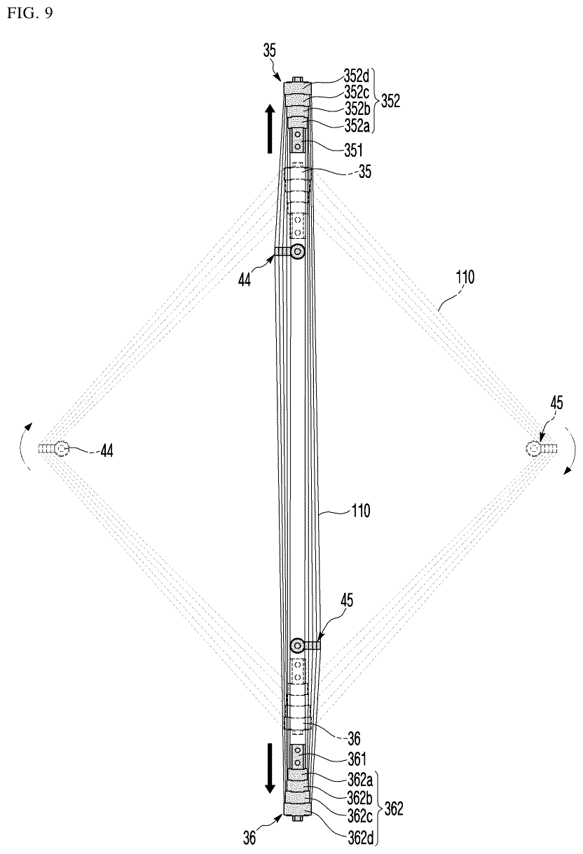

FIGS. 7 to 9 illustrate the winding process of the metal wire (110). As shown in FIG. 7, the metal wire roller (100) is mounted on the roller mounting portion (50). The metal wire (110) is wound sequentially from the inner side of the winding bars. As depicted in FIG. 7, the vertical body unit (30) and the horizontal body unit (40) are fixed by the stopper (46) in a cross (“+”) shape, with the upper frame (332) and lower frame (333) removed. Then, the handle (3221) is used to rotate both the vertical body unit (30) and the horizontal body unit (40) together. As the vertical body unit (30) and the horizontal body unit (40) rotate, the metal wire (110) is first wound onto the upper winding bar (3511), the lower winding bar (3611), the front winding bar (441), and the rear winding bar (451). The metal wire (110) is wound in a single line at uniform intervals without overlapping. Once the winding of the lowest winding bars (3511, 3611, 441, 451) is completed, the upper layered winding bar (3521) is connected to the upper winding bar (3511), the lower layered winding bar (3621) is connected to the lower winding bar (3611), the front layered winding bar (443) is connected to the front winding bar (441), and the rear layered winding bar (453) is connected to the rear winding bar (451), respectively. After the connections are completed, the metal wire (110) is wound onto the upper layered winding bar (3521), the lower layered winding bar (3621), the front layered winding bar (443), and the rear layered winding bar (453). This process is repeated sequentially, winding the metal wire (110) layer by layer. FIG. 8 shows the state where the metal wire (110) is wound onto the vertical body unit (30) and the horizontal body unit (40). Although only a single wire is illustrated in the figure, as shown in FIG. 9, additional layers of metal wire (110) can be formed, wound at uniform intervals front-to-back using the layered winding bars. FIG. 9 illustrates that after the winding of the metal wire (110) is completed, the stopper (46) of the horizontal body unit (40) is released, and the horizontal body unit (40) is rotated so that it aligns vertically with the vertical body unit (30). Furthermore, FIG. 9 shows that when the horizontal body unit (40) rotates, the front wire seating portion (44) and the rear wire seating portion (45) also rotate accordingly, maintaining a uniform interval front-to-back for the vertically connected metal wires (110). Once the horizontal body unit (40) is aligned vertically with the vertical body unit (30), the stopper (46) is re-secured to fix the position of the horizontal body unit (40). Additionally, when the horizontal body unit (40) rotates and aligns vertically with the vertical body unit (30), the metal wire (110) becomes loose. If the metal wire (110) loosens, it may be damaged. To prevent this, the upper wire seating portion (35) is moved

to the upper end of the side frame (331) by loosening the upper bolt (3535) with the help of the upper spring (3534) of the upper joint part (353), while the lower wire seating part (36) is moved to the lower end of the side frame (331) by loosening the lower bolt (3635) with the assistance of the lower spring (3635) of the lower joint part (363), thereby ensuring that the metal wire (110) remains taut. The upper winding bar (351) and the upper layered winding bar (352) gradually widen from the bottom to the top, and similarly, the lower winding bar (361) and the lower layered winding bar (362) gradually widen from the top to the bottom. Consequently, the wires (110) wound front-to-back maintain a consistent spacing, preventing interference between them.

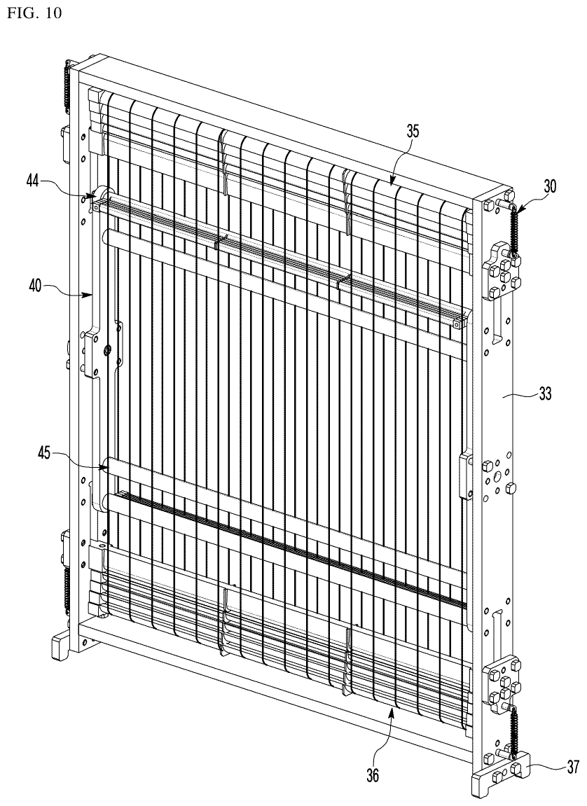

FIG. 10 illustrates the configuration prepared for insertion into a deposition device (not shown). Since it is advantageous for the part inserted into the deposition device to have a minimal volume, in the case of the vertical body unit (30), only the vertical frame (33), the upper wire seating portion (35), and the lower wire seating portion (36) remain, while the rest is removed. The horizontal body unit (40), being positioned inside the vertical body unit (30), is inserted as is. Consequently, a partial configuration of the vertical body unit (30) and the horizontal body unit (40) are fed into the deposition device, enabling graphene deposition on the large amount of metal wire (110) that has been wound. This approach offers the advantage of increased production efficiency.

While the embodiments of the present invention have been described above, it will be understood by those skilled in the art to which the present invention pertains that various modifications can be made without departing from the scope of the claims of the present invention.

1. A metal wire bobbin device for graphene deposition, comprising:
a vertical body unit including a vertical frame with open front and rear sides, and a vertical wire seating portion installed on the vertical frame; and
a horizontal body unit rotatably installed inside the vertical body unit, including a horizontal frame and a horizontal wire seating portion installed on the horizontal frame.

2. The metal wire bobbin device for graphene deposition according to claim 1, wherein the vertical body unit comprises:
a pair of support shafts installed on both sides of the center of the vertical frame;
a rotational drive portion consisting of a pair of drive shafts installed on the inner sides of the support shafts to rotationally drive the horizontal body unit, and a handle provided on one of the drive shafts;
a vertical frame consisting of a pair of side frames where the support shafts are installed, an upper frame connecting the tops of the side frames, and a lower frame connecting the bottoms of the side frames; and
a vertical wire seating portion consisting of an upper wire seating portion mounted on the upper part of the side frames and a lower wire seating portion mounted on the lower part of the side frames.

3. The metal wire bobbin device for graphene deposition according to claim 2,
wherein the upper wire seating portion comprises: an upper winding part including an upper winding bar on which the metal wire is wound on its upper surface, and a pair of upper joint hole parts formed at both ends of the upper winding bar; and a pair of upper joint parts fastened to the upper joint hole parts from the outside of the side frame to secure both sides of the upper winding part to the side frame,
wherein the lower wire seating portion comprises: a lower winding part including a lower winding bar on which the metal wire is wound on its lower surface, and a pair of lower joint hole parts formed at both ends of the lower winding bar; and a pair of lower joint parts fastened to the lower joint hole parts from the outside of the side frame to secure both sides of the lower winding part to the side frame.

4. The metal wire bobbin device for graphene deposition according to claim 3,
wherein the upper joint part comprises: an upper joint plate with multiple bolt holes, an upper spring first support end mounted on the upper joint plate, an upper spring second support end mounted on the top of the side frame, an upper spring connecting the upper spring first and second support ends, and multiple upper bolts fastening the upper joint plate to the side frame and the upper joint hole part, and
wherein the lower joint part comprises: a lower joint plate with multiple bolt holes, a lower spring first support end mounted on the lower joint plate, a lower spring second support end mounted on the bottom of the side frame, a lower spring connecting the lower spring first and second support ends, and multiple lower bolts fastening the lower joint plate to the side frame and the lower joint hole part.

5. The metal wire bobbin device for graphene deposition according to claim 4,
wherein the side frame is provided with an upper guide hole and a lower guide hole of a predetermined length, allowing upward and downward movement due to the elastic force of the upper spring and lower spring, respectively, when some of the upper bolts and lower bolts fastened to the side frame through the upper joint plate and lower joint plate are removed.

6. The metal wire bobbin device for graphene deposition according to claim 5,
wherein the upper wire seating portion is further equipped with multiple upper layered winding parts above the upper winding part, with the width of the upper layered winding parts increasing progressively from lower layer to upper layer, and
wherein the lower wire seating portion is further equipped with multiple lower layered winding parts below the lower winding part, with the width of the lower layered winding parts increasing progressively from upper layer to lower layer.

7. The metal wire bobbin device for graphene deposition according to claim 6,
wherein the upper layered winding parts comprise multiple upper layered winding bars sequentially stacked above the upper winding bar and upper fixing fasteners formed on both sides of the upper layered winding bars, and
wherein the lower layered winding parts comprise multiple lower layered winding bars sequentially stacked below the lower winding bar and lower fixing fasteners formed on both sides of the lower layered winding bars.

8. The metal wire bobbin device for graphene deposition according to claim 7,
wherein the horizontal body unit comprises:
a pair of rotating shafts mounted on the inner sides of the side frame, connected to the drive shaft for rotation, with one of the rotating shafts connected to the drive shaft equipped with the handle, enabling simultaneous rotation by the handle's operation;
a horizontal frame comprising a pair of side bodies where the rotating shafts are mounted, a front body connecting the front ends of the side bodies, and a rear body connecting the rear ends of the side bodies; and
a horizontal wire seating portion comprising a front wire seating portion mounted at the front end of the side bodies and a rear wire seating portion mounted at the rear end of the side bodies.

9. The metal wire bobbin device for graphene deposition according to claim 8,
wherein the front wire seating portion comprises a front winding bar on which the metal wire is wound on its front surface, and a pair of front joint bolts for securing both sides of the front winding bar to the side body, and
wherein the rear wire seating portion comprises a rear winding bar on which the metal wire is wound on its rear surface, and a pair of rear joint bolts for securing both sides of the rear winding bar to the side body.

10. The metal wire bobbin device for graphene deposition according to claim 9,
wherein the front wire seating portion is further equipped with multiple front layered winding bars mounted in front of the front winding bar, and
wherein the rear wire seating portion is further equipped with multiple rear layered winding bars mounted behind the rear winding bar.

11. The metal wire bobbin device for graphene deposition according to claim 10,
wherein the front wire seating portion can be rotated or fixed using the front joint bolts, and
wherein the rear wire seating portion can be rotated or fixed using the rear joint bolts.
